(19) United States
(12) Patent Application Publication
(10) Pub. No.: US 2010/0183042 A1
(43) Pub. Date: Jul. 22, 2010

(54) OPTICAL DIODE STRUCTURE AND MANUFACTURING METHOD THEREOF

(75) Inventors: Mount-Learn Wu, Taoyuan (TW); Jenq-Yang Chang, Taoyuan (TW); Yun-Chih Lee, Taoyuan (TW); Shih-Pu Yang, Taoyuan (TW)

Correspondence Address: KIRTON AND MCCONKIE, 60 EAST SOUTH TEMPLE,, SUITE 1800, SALT LAKE CITY, UT, 84111, US

(73) Assignee: NATIONAL CENTRAL UNIVERSITY, Taoyuan (TW)

(21) Appl. No.: 12/689,492

(22) Filed: Jan. 19, 2010

(30) Foreign Application Priority Data
Jan. 16, 2009 (TW) 098101596

(51) Int. Cl. H01S 5/343; H01L 33/00; H01L 21/302

(52) U.S. Cl. 372/45.012; 257/13; 438/29; 257/E33.008; 257/E33.074; 257/E21.214

(57) ABSTRACT

An optical diode structure includes a semiconductor substrate, a luminous layer, a first type semiconductor layer and a second type semiconductor. The luminous layer is disposed over the semiconductor substrate for emitting light. The first type semiconductor layer is formed between the semiconductor substrate and the luminous layer. The second type semiconductor layer has a first surface and a second surface. The first surface is in contact with the luminous layer. A rough-surfaced grating structure is formed in the second surface for modulating the light emitted by the luminous layer, thereby increasing light extraction efficiency of the luminance layer.

### FIELD OF THE INVENTION

The present invention relates to an optical diode structure, and more particularly to an optical diode structure having a rough-surfaced grating. The present invention also relates to a method of manufacturing such an optical diode structure.

### BACKGROUND OF THE INVENTION

A light emitting diode (LED) is a semiconductor device capable of converting electrical energy into visible light and radiation energy when electric current flows between the anode electrode and the cathode electrode due to a voltage applied on both terminals of the semiconductor device. When an electric current passes through the LED in the forward direction, electrons recombine with holes and the extra energy is released in the form of light. The wavelength of the emitted light corresponds to the material and the energy associated with electron-hole pair recombination. The advantages of using the LED include a low operating voltage, low power consumption, high illuminating efficiency, very short response time, pure light color, high structural firmness, high impact resistance, excellent performance reliability, light weight, cost effectiveness, long service life, and so on. With increasing development of material science, the current LEDs could emit a variety of colors. The conventional LEDs are made from a variety of inorganic semiconductor materials. For example, the LED made of gallium aluminum arsenide (AlGaAs) could emit red light or infrared ray; the LED made of aluminum gallium phosphide (AlGaP) could emit green light, the LED made of gallium nitride (GaN) could emit blue light. As the demands on the multi-color and high brightness are increased, three primary colors (i.e. red, green and blue) LEDs are used to produce resulting light with desired color and brightness. For the reason, GaN-based light-emitting diodes (GaN LEDs) that emit blue light have experienced great growth and are now rapidly gaining in popularity.

GaN LEDs are becoming more and more appealing in various applications due to their superior performances of energy efficiency, high reliability, and versatile colors. The applications of the GaN LEDs include for example data storage technology, large-sized full color display panels, indicator lights and various lighting devices. In a case that GaN LEDs are applied to lighting devices, several characteristics such as brightness, color uniformity, and uniform irradiance should be taken into account. Among these characteristics, the brightness is the most important. Generally, the brightness is strongly related to output efficiency of GaN LEDs. The output efficiency of a LED is also referred as external quantum efficiency. The external quantum efficiency is equal to a product of the internal quantum efficiency of the LED and the light extraction efficiency of the LED. The internal quantum efficiency of the LED is the electric-light conversion efficiency of the LED. The internal quantum efficiency of the LED is related to band gap energy, defects, impurities and epitaxy composition and structure of the LED. The light extraction efficiency of the LED is defined as the number of photons emitted into the free space relative to the number of photons emitted from the active region of the LED after the light is absorbed, refracted and reflected by the LED. In other words, light extraction efficiency is dependent on several factors such as light absorption, geometry, refraction index and scatting property of the LED. That is, the product of the internal quantum efficiency of the LED and the light extraction efficiency of the LED is equal to the output efficiency of the LED.

From the above discussion, the light extraction efficiency could be increased by adjusting the material, geometry and scatting property of the LED. As the light extraction efficiency is increased, the output efficiency of the LED is increased. Since the GaN LEDs are becoming more and more appealing, it is critical to improve the output efficiency of the GaN LEDs.

FIG. 1 is a schematic view illustrating a GaN LED structure according to the prior art. Hereinafter, a process of manufacturing the GaN LED structure will be illustrated with reference to FIG. 1. Firstly, a silicon substrate 10 is provided. Then, a reflective layer 11, a cathode electrode layer 12, a luminous structure 13 and an anode electrode layer 14 are successively stacked on the silicon substrate 10. The luminous structure 13 comprises a P-type gallium nitride semiconductor layer 131, an active layer 132 (or a luminous layer) and an N-type gallium nitride semiconductor layer 133. For increasing the light extraction efficiency of the GaN LED structure 1, a roughening structure 1330 is formed on the surface of the N-type gallium nitride semiconductor layer 133. As such, the GaN LED structure 1 has a rough-surfaced luminous structure 13.

Although the rough-surfaced luminous structure 13 is effective for increasing the light extraction efficiency of GaN LED structure 1, the improvement is still insufficient. Therefore, there is a need of providing an optical diode structure having enhanced light extraction efficiency.

### SUMMARY OF THE INVENTION

The present invention provides an optical diode structure having enhanced light extraction efficiency.

In accordance with an aspect of the present invention, there is provided an optical diode structure. The optical diode structure includes a semiconductor substrate, a luminous layer, a first type semiconductor layer and a second type semiconductor. The luminous layer is disposed over the semiconductor substrate for emitting light. The first type semiconductor layer is formed between the semiconductor substrate and the luminous layer. The second type semiconductor layer has a first surface and a second surface. The first surface is in contact with the luminous layer. A rough-surfaced grating structure is formed in the second surface for modulating the light emitted by the luminous layer, thereby increasing light extraction efficiency of the luminance layer.

In accordance with another aspect of the present invention, there is provided a process of manufacturing an optical diode structure. The process includes steps of: providing a semiconductor substrate, forming a luminous structure over the semiconductor substrate, forming a roughening region in the luminous structure, performing a photolithography and etching procedure on the luminous structure, thereby forming a rough-surfaced grating structure in the roughening region of the luminous structure.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic view illustrating a GaN LED according to the prior art;

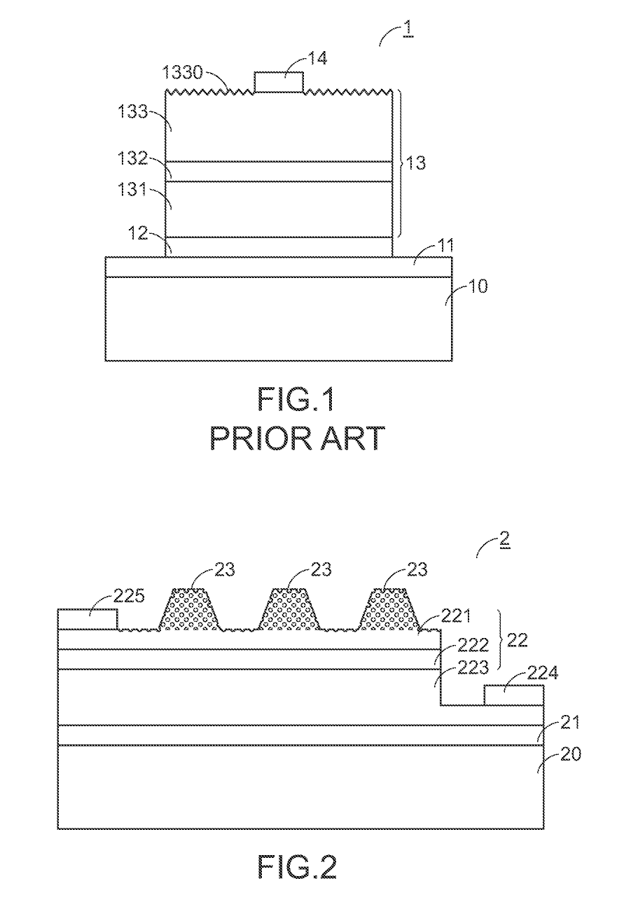

FIG. 2 is a schematic view illustrating an optical diode structure according to an embodiment of the present invention;

FIGS. 3A and 3B are schematic views illustrating two exemplary rough-surfaced grating structures of the optical diode structure according to the present invention; and

FIGS. 4A˜4E are schematic views illustrating a process of manufacturing an optical diode structure according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

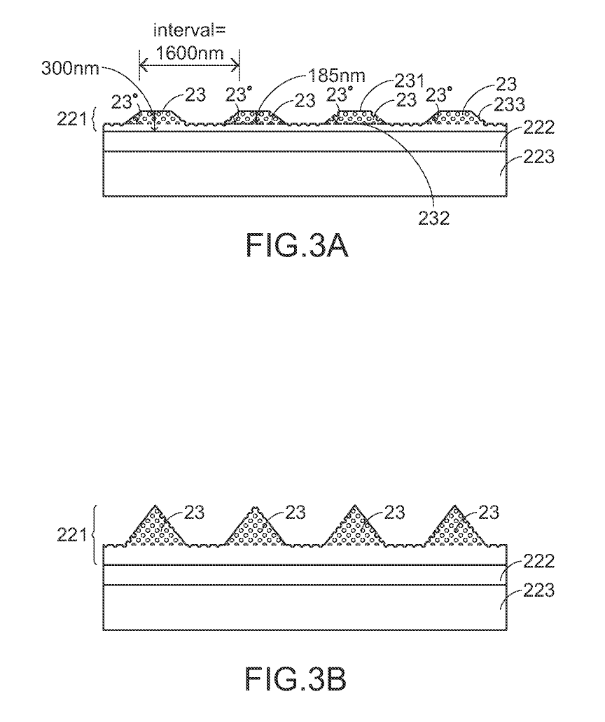

The present invention provides an optical diode structure having enhanced light extraction efficiency. FIG. 2 is a schematic view illustrating an optical diode structure according to an embodiment of the present invention. An example of the optical diode structure includes but is not limited to a light emitting diode (LED) or a laser diode. Hereinafter, the present invention will be illustrated by referring to a light emitting diode (LED) structure. As shown in FIG. 2, the LED structure 2 comprises a semiconductor substrate 20, a reflective layer 21 and a luminous structure 22. The semiconductor substrate 20 is for example a sapphire semiconductor substrate or a silicon wafer semiconductor substrate with any lattice orientation. The reflective layer 21 is arranged between the semiconductor substrate 20 and the luminous structure 22. The reflective layer 21 is made of a highly reflective metallic material such as aluminum (Al), silver (Ag), or aluminum-silver alloy. The luminous structure 22 is formed on the reflective layer 21. In accordance with a key feature of the present invention, a rough-surfaced grating structure 23 is formed on a surface of the luminous structure 22.

When the light emitted by the luminous structure 22 passes through the rough-surfaced grating structure 23, the light confined within the luminous structure 22 could be modulated by the rough-surfaced grating structure 23. For example, by using the rough-surfaced grating structure 23, the emitting angle of the light emitted by the luminous structure 22 may be increased and the light of high spatial frequency may be extracted from the luminous structure 22. Due to the superposition effect of the rough surface and the grating of the rough-surfaced grating structure 23, the light extraction efficiency of the LED structure 2 is increased.

Please refer to FIG. 2 again. The luminous structure 22 of the LED structure 2 is made of a semiconductor material selected from aluminum nitride (AlN), gallium nitride (GaN), indium nitride (InN) or indium gallium nitride (InGaN). The luminous structure 22 comprises a P-type semiconductor layer 221, a luminous layer 222 and an N-type semiconductor layer 223. The N-type semiconductor layer 223, the luminous layer 222 and the P-type semiconductor layer 221, are successively stacked on the semiconductor substrate 20 by a metal organic chemical vapor deposition (MOCVD) procedure. As shown in FIG. 2, the N-type semiconductor layer 223 is disposed over the semiconductor substrate 20 and formed on the reflective layer 21. The P-type semiconductor layer 221 is formed on the luminous layer 222. Moreover, a cathode electrode 224 and an anode electrode 225 are formed on the N-type semiconductor layer 223 and the P-type semiconductor layer 221, respectively. The cathode electrode 224 and the anode electrode 225 are made of Cr/Au. The cathode electrode 224 and the anode electrode 225 are electrically connected to a cathode electrode and an anode electrode of an external circuit (not shown). The luminous layer 222 is arranged between the N-type semiconductor layer 223 and the P-type semiconductor layer 221. The luminous layer 222 has a multi-quantum well (MQW) structure. The multi-quantum well structure is effective for reducing electron leakage current in order to increase the output efficiency and the internal quantum efficiency of the LED structure 2. After the cathode electrode 224 and the anode electrode 225 are electrically connected to the cathode electrode and the anode electrode of the external circuit, respectively, the luminous layer 222 will emit light.

For providing the rough-surfaced grating structure 23, a roughening region is firstly formed in the surface of the P-type semiconductor layer 221 by controlling the epitaxy parameters of the MOCVD procedure or using an etching procedure. Next, by a photolithography and etching procedure, sub-wavelength structures are formed in the roughening region of the P-type semiconductor layer 221 in a regular arrangement, thereby producing the rough-surfaced grating structures 23. Since the LED structure 2 of the present invention has the nano/micro rough-surfaced grating structure 23, the light extraction efficiency is largely enhanced when compared with the conventional LED structure.

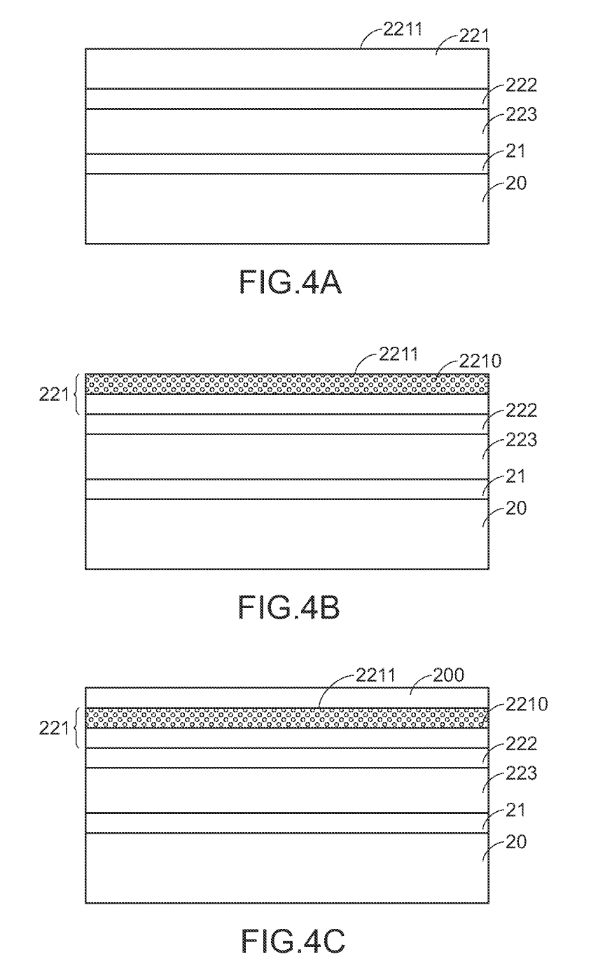

FIG. 3A is a schematic view illustrating an exemplary rough-surfaced grating structure of the optical diode structure according to the present invention. As shown in FIG. 3A, the grating structures 23 formed in the roughening region of the P-type semiconductor layer 221 are discretely arranged at regular intervals. In this embodiment, the interval between any two grating structures 23 is 1600 nm. In addition, the grating structure 23 is a trapezoid-shaped structure including a top surface 231 and a bottom surface 232. The area of the top surface 231 is smaller than that of the bottom surface 232. An included angle between a bevel edge 233 and the bottom surface 232 of the grating structure 23 is 23 degrees. Generally, the conventional LED structure could be considered as a point light source because the light emitted from LED structure is randomly reflected by surrounding components in a complex manner. Whereas, due to the trapezoid-shaped grating structure 23, the light emitted from the LED structure 2 of the present invention is initially modulated by the grating structure 23 to have an increased cone angle. In other words, the bevel edge of the trapezoid-shaped grating structure 23 facilitates increasing the cone angle, thereby increasing the light extraction amount. The light that is initially modulated by the grating structure 23 will be further modulated and scatted by the rough surface of the grating structure 23, so that the cone angle is further increased. In other words, the synergistic effect generated by these two modulations will increase the light extraction angle so as to increase the light extraction amount of the LED structure. FIG. 3B is a schematic view illustrating another exemplary rough-surfaced grating structure of the optical diode structure according to the present invention. As shown in FIG. 3B, the grating structure 23 is a triangular-shaped structure.

Please refer to FIG. 3A again. The height of the P-type semiconductor layer 221 before the etching procedure is done is 300 nm. After the etching procedure, the rough-surfaced grating structure 23 having a height (or thickness) of 185 nm is formed. That is, the height (or thickness) of the remaining P-type semiconductor layer 221 is 115 nm. It is found that the height (or thickness) of the rough-surfaced grating structure 23 is larger than the height (or thickness) of the remaining P-type semiconductor layer 221.

From the above description, the optical diode structure of the present invention has a rough-surfaced grating structure 23, which is formed in the surface of the luminous structure 22 (or in the surface of the P-type semiconductor layer 221). The rough-surfaced grating structure 23 is effective for modulating the light emitted by the luminous structure 22, thereby increasing the light extraction efficiency of the optical diode structure. In addition, the rough-surfaced grating structures 23 are produced by forming a roughening region in the surface of the luminous structure 22 (or in the surface of the P-type semiconductor layer 221) and then forming regularly-arranged sub-wavelength structures in the roughening region. Due to the rough-surfaced grating structure 23, the light extraction efficiency is largely enhanced when compared with the conventional LED structure.

In the above embodiments, the P-type semiconductor layer 221, the luminous layer 222 and the N-type semiconductor layer 223 of the luminous structure 22 are stacked from top to bottom. Alternatively, the N-type semiconductor layer 223, the luminous layer 222 and the P-type semiconductor layer 221 of the luminous structure 22 could be stacked from top to bottom to provide another stacked order.

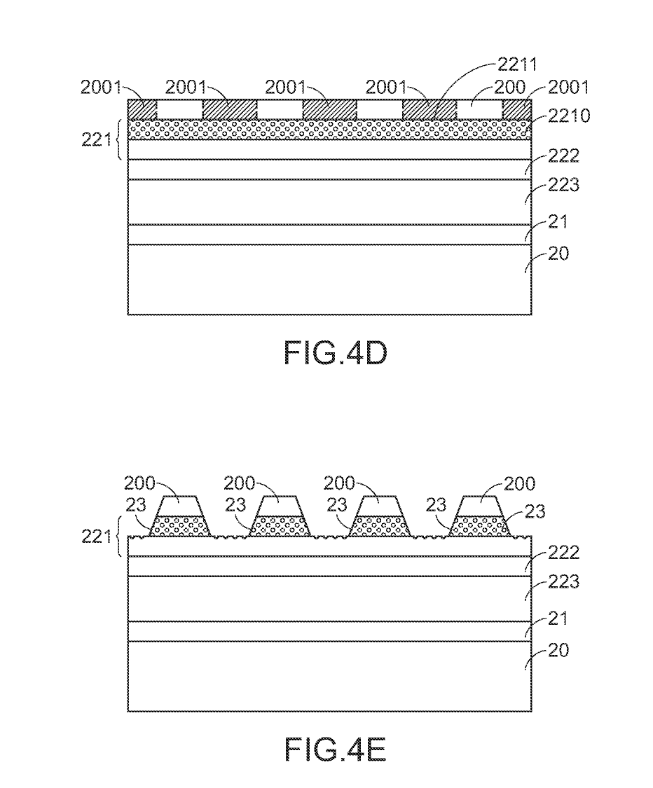

FIGS. 4A˜4E are schematic views illustrating a process of manufacturing an optical diode structure according to an embodiment of the present invention. First of all, as shown in FIG. 4A, a semiconductor substrate 20 (e.g. a sapphire semiconductor substrate or a silicon wafer semiconductor substrate) with any lattice orientation is provided. Next, a reflective layer 21 is formed on the semiconductor substrate 20 by a metal organic chemical vapor deposition (MOCVD) procedure. Successively, an N-type semiconductor layer 223 is formed on the reflective layer 21, a luminous layer 222 is formed on the N-type semiconductor layer 223, and a P-type semiconductor layer is formed on the luminous layer 222. Next, by a wet etching procedure, a roughening region 2210 is formed in the surface 2211 of the P-type semiconductor layer 221 (see FIG. 4B). Next, a photoresist layer 200 is formed on the roughening region 2210 of the P-type semiconductor layer 221 by a photolithography and etching procedure (see FIG. 4C). Next, as shown in FIG. 4D, a photoresist pattern 2001 defined by a photomask (not shown) is formed on the photoresist layer 200. Next, a rough-surfaced grating structure 23 is formed in the roughening region 2210 of the P-type semiconductor layer 221 by a dry etching procedure according to the photoresist pattern 2001 (see FIG. 4E). After the residual photoresist is removed, an anode electrode 225 and a cathode electrode 224 are respectively formed on the P-type semiconductor layer 221 and the N-type semiconductor layer 223. Meanwhile, the LED structure 2 of FIG. 2 is fabricated.

In the above embodiment, the roughening region 2210 is formed in the surface 2211 of the P-type semiconductor layer 221 by a wet etching procedure (see FIG. 4B). In some embodiments, the roughening region 2210 is produced during the metal organic chemical vapor deposition (MOCVD) procedure.

From the above description, the optical diode structure of the present invention has rough-surfaced grating structures. The rough-surfaced grating structures are produced by forming a roughening region in the surface of the luminous structure and then forming regularly-arranged sub-wavelength grating structures in the roughening region. The light emitted from the optical diode structure of the present invention is initially modulated by the grating structure to have an increased cone angle. The light that is initially modulated by the grating structure is further modulated and scatted by the rough surface of the grating structure, so that the cone angle is further increased. In other words, the synergistic effect generated by these two modulations will increase the light extraction angle so as to increase the light extraction amount of the optical diode structure. When compared with the conventional optical diode structure, the light extraction efficiency of the optical diode structure of the present invention is increased by at least seven to ten times in order to obviate the drawbacks encountered in the prior art.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An optical diode structure, comprising:
a semiconductor substrate;
a luminous layer disposed over the semiconductor substrate for emitting light;
a first type semiconductor layer formed between the semiconductor substrate and the luminous layer; and
a second type semiconductor layer having a first surface and a second surface, wherein the first surface is in contact with the luminous layer, and a rough-surfaced grating structure is formed in the second surface for modulating the light emitted by the luminous layer, thereby increasing light extraction efficiency of the luminance layer.

2. The optical diode structure according to claim 1 wherein the optical diode structure is a light emitting diode structure or a laser diode structure.

3. The optical diode structure according to claim 1 wherein the semiconductor substrate is a sapphire semiconductor substrate or a silicon wafer semiconductor substrate with any lattice orientation.

4. The optical diode structure according to claim 1 wherein each the first type semiconductor layer, the second type semiconductor layer and the luminous layer is made of a semiconductor material selected from aluminum nitride, gallium nitride, indium nitride or indium gallium nitride.

5. The optical diode structure according to claim 1 further comprising:
a reflective layer arranged between the semiconductor substrate and the first type semiconductor layer, wherein the reflective layer is made of a highly reflective metallic material selected from aluminum, silver or aluminum-silver alloy;
a first electrode formed on the first type semiconductor layer and electrically connected to a first electrode of an external circuit; and
a second electrode formed on the second type semiconductor layer and electrically connected to a second electrode of the external circuit.

6. The optical diode structure according to claim 5 wherein the first type semiconductor layer is a P-type semiconductor layer, the first electrode of the optical diode structure and the first electrode of the external circuit are anode electrodes, the second type semiconductor layer is an N-type semiconductor layer, and the second electrode of the optical diode structure and the second electrode of the external circuit are cathode electrodes.

7. The optical diode structure according to claim 5 wherein the first type semiconductor layer is an N-type semiconductor layer, the first electrode of the optical diode structure and the first electrode of the external circuit are cathode electrodes, the second type semiconductor layer is a P-type semiconductor layer, the second electrode of the optical diode structure and the second electrode of the external circuit are anode electrodes.

8. The optical diode structure according to claim 1 wherein the luminous layer has a multi-quantum well structure.

9. The optical diode structure according to claim 1 wherein the rough-surfaced grating structure is a trapezoid-shaped structure having a top surface and a bottom surface, and the area of the top surface is smaller than that of the bottom surface.

10. A process of manufacturing an optical diode structure, the process comprising steps:
providing a semiconductor substrate;
forming a luminous structure over the semiconductor substrate;
forming a roughening region in the luminous structure; and
performing a photolithography and etching procedure on the luminous structure, thereby forming a rough-surfaced grating structure in the roughening region of the luminous structure.

11. The process according to claim 10 wherein the semiconductor substrate is a sapphire semiconductor substrate or a silicon wafer semiconductor substrate with any lattice orientation.

12. The process according to claim 10 wherein each the first type semiconductor layer, the second type semiconductor layer and the luminous layer is made of a semiconductor material selected from aluminum nitride, gallium nitride, indium nitride or indium gallium nitride.

13. The process according to claim 10 wherein the luminous structure is formed over the semiconductor substrate according to a metal organic chemical vapor deposition procedure, which comprises steps of:
forming a first type semiconductor layer on the semiconductor substrate;
forming a luminous layer on the first type semiconductor layer; and
forming a second type semiconductor layer on the luminous layer, thereby producing the luminous structure.

14. The process according to claim 13, further comprising steps of:
forming a reflective layer between the semiconductor substrate and the first type semiconductor layer, wherein the reflective layer is made of a highly reflective metallic material selected from aluminum, silver or aluminum-silver alloy;
forming a first electrode on the first type semiconductor layer; and
forming a second electrode on the second type semiconductor layer.

15. The process according to claim 14 wherein the first type semiconductor layer is a P-type semiconductor layer, the first electrode of the optical diode structure is an anode electrode, the second type semiconductor layer is an N-type semiconductor layer, and the second electrode of the optical diode structure is a cathode electrode.

16. The process according to claim 14 wherein the first type semiconductor layer is an N-type semiconductor layer, the first electrode of the optical diode structure is a cathode electrode, the second type semiconductor layer is a P-type semiconductor layer, and the second electrode of the optical diode structure is an anode electrode.

17. The process according to claim 13 wherein the roughening region is formed in the luminous structure by a wet etching procedure.

18. The process according to claim 13 wherein the roughening region is formed on the luminous structure during the metal organic chemical vapor deposition procedure.

19. The process according to claim 10 wherein the photolithography and etching procedure comprises steps of:
forming a photoresist layer on the roughening region of the luminous structure;
defining a photoresist pattern on the photoresist layer by a photomask; and
performing a dry etching procedure on the luminous structure according to the photoresist pattern, thereby producing the rough-surfaced grating structure in the roughening region of the luminous structure

20. The process according to claim 10 wherein the rough-surfaced grating structure is a trapezoid-shaped structure having a top surface and a bottom surface, and the area of the top surface is smaller than that of the bottom surface.
